(19) United States
(12) Patent Application Publication
(10) Pub. No.: US 2007/0262296 A1
(43) Pub. Date: Nov. 15, 2007

(54) Photodetectors employing germanium layers

(76) Inventor: Matthias Bauer, Phoenix, AZ (US)

Correspondence Address: KNOBBE, MARTENS, OLSEN & BEAR LLP, 2040 MAIN STREET, FOURTEENTH FLOOR, IRVINE, CA, 92614, US

(21) Appl. No.: 11/433,200

(22) Filed: May 11, 2006

(51) Int. Cl. H01L 31/00

(52) U.S. Cl. 257/19

(57) ABSTRACT

A germanium-based photodetector comprises a p- (or n-type) germanium layer, an intrinsic single crystal germanium layer formed on the p- (or n-) type germanium layer, and an n- (or p-type) germanium layer formed on the intrinsic single crystal germanium layer. An electrically conductive contact extends vertically from an upper surface of the photodetector device downward to the buried layer. Electrodes formed on the upper surface of the photodetector device define front side contacts.

### BACKGROUND OF THE INVENTION

1. Field of the Invention

The invention relates to photodetectors and, in particular, to photodetectors employing germanium layers.

2. Description of the Related Art

Photodetectors are semiconductor devices that convert optical signals into electric signals. The operation of a photodetector involves the steps of generating a carrier by incident light, transporting the carrier to generate a current and generating an output signal through interaction of the current with an external signal. When light is absorbed by the photodetector, electron-hole pairs are generated and separated by an electric field to produce a photo-current (current) through the device. Photodetectors have found widespread use in the communications industry, such as in fiber optical communication devices, which typically employ light with wavelengths of 1300-1550 nanometers (nm).

Demand for high-speed optical telecommunication devices has motivated efforts directed at overcoming the spectral limitation of silicon (Si) photodetectors. Due to the inherently high band-gap of silicon, Si-based photodetectors are not ideal at wavelengths of 1300-1550 nm (i.e., near infrared) for medium and long-haul optical fiber communication. To overcome such limits, photodetectors based on materials with significantly lower band gaps are required for use in large scale integration (LSI) of photonic integrated circuits on a chip for use in high speed (broadband) communication.

Efforts geared towards cost-effective integration of photodetectors in Si have primarily focused on the integration of group III-V semiconductors, such as InGaAs, and the integration of Ge and SiGe alloys. The instability of InGaAs at high temperatures limits its use in the back-end of Si process technology because In, Ga and As, which are typically used as dopants in Si, phase segregate at high temperatures, thus adversely affecting device performance. Phase segregation of Ge and SiGe, however, is not a problem.

The compatibility of a Ge epitaxial process with front and back-end Si complementary metal oxide semiconductor (CMOS) technology has been demonstrated by the recent commercial success of bipolar CMOS (BiCMOS) devices. Due to the compatibility of Ge with commercial Si CMOS technology and the low band gap (0.8 eV) of Ge grown on Si, Ge-based photodetectors (photodiodes) offer great promise for use in the next generation of optoelectronics.

A p-i-n (or n-i-p) photodetector typically includes a thin, heavily doped n- (or p-) type Ge layer, an intrinsic Ge layer and a p- (or n-) type Si substrate. A key challenge to forming p-i-n (or n-i-p) Ge-based photodetectors is the lattice mismatch between Ge deposited on Si, which effects lattice strain. Lattice strain significantly influences device performance.

Lattice strain can result in the formation of defects. Lattice strain is typically due to the heteroepitaxial deposition of germanium layers or films. A “heteroepitaxial” deposited layer is an epitaxial or single crystal film that has a different composition than the single crystal substrate onto which it is deposited. A deposited epitaxial layer is said to be “strained” when it is constrained to have a lattice structure in at least two dimensions that is the same as that of the underlying single crystal substrate but different from its inherent lattice constant. Lattice strain occurs because the atoms in the deposited film depart from the positions that they would normally occupy in the lattice structure of the free-standing, bulk material when the film epitaxially deposits so that its lattice structure matches that of the underlying single crystal substrate.

Heteroepitaxial deposition of a germanium-containing material, such as silicon germanium or germanium itself, onto a single crystal silicon substrate—such as a wafer or an epitaxial silicon layer—generally produces compressive lattice strain because the lattice constant of the deposited germanium-containing material is larger than that of the silicon substrate. The degree of strain is related to the thickness of the deposited layer and the degree of lattice mismatch between the deposited material and the underlying substrate. Additionally, greater amounts of germanium generally increase the amount of strain in the germanium-containing layer. Specifically, the higher the germanium content, the greater the lattice mismatch with the underlying silicon, up to pure germanium, which has a 4% greater lattice constant compared to silicon.

As the thickness of the germanium-containing layer increases above a certain thickness, called the critical thickness, the germanium-containing layer relaxes to its inherent lattice constant. This relaxation requires the formation of misfit dislocations at the film/substrate interface. The critical thickness depends on several factors, such as, e.g., temperature. That is, the higher the temperature, the lower the critical thickness. The critical thickness also depends on the degree of mismatch due to germanium content. That is, the higher the germanium content, the lower the critical thickness.

When Ge (or SiGe) is deposited on a Si wafer, misfit-dislocations, which are produced by lattice mismatch relaxation, cause residual threading dislocations in the Ge epilayer, which adversely affect photodetector performance. Due to the 4% lattice mismatch, the epitaxial growth of Ge on Si introduces a significant amount of strain on the Ge epilayer. When the Ge layer thickness exceeds a certain critical value, defects form. Consequently, it is difficult to obtain Ge films with suitable characteristics (e.g., thicknesses) appropriate for maximum efficiency; topography compatible with submicron lithography; and minimum defect densities required for high-speed devices. Consequently, threading dislocations impede the practical application of Ge-based photodetectors in large scale integration.

Several approaches have been proposed for growing Ge epitaxial films above the critical thickness. For example, thick graded buffers can partially relax the strain and let the overall structure evolve in thickness. A Ge p-i-n photodetector consisting of a compositional graded intermediate layer is known in the art and described in U.S. Pat. No. 4,514,748, issued to Bean et al., the entire disclosure of which is incorporated herein by reference. Although the graded buffer is able to solve the lattice mismatch problem, the growth of this structure requires deposition times much longer than that for the overlying active layer, thus significantly increasing the overall processing cost and time.

Aside from the material limitations of current Ge-based photodetectors, the physical characteristics of these devices must be carefully crafted for use in large scale integration. Typically, Ge-based detectors are built on highly-doped substrates, enabling contacting from the backside of the wafer. However, this leads to isolated devices, making their integration into circuits difficult.

Accordingly, there is a need for structures and methods for forming Ge-based photodetectors with reduced threading dislocations, especially where the design comprises a geometry that is well-suited for large scale integration and incorporation into electronics circuitry.

### SUMMARY OF THE INVENTION

According to one aspect of the invention, a photodetector device is provided. The device comprises a substrate; a first doped germanium-containing layer formed on the substrate or on one or more intervening layers, the first doped germanium-containing layer defining a buried layer; a substantially monocrystalline germanium-containing layer formed on the buried layer; a second doped germanium-containing layer formed on the monocrystalline germanium layer, the second doped germanium-containing layer defining a contact layer; and an electrically conductive contact extending vertically from an upper surface of the photodetector device downward to the buried layer, the electrically conductive contact being substantially electrically insulated from the monocrystalline germanium-containing layer and the second doped germanium-containing layer, wherein the first doped germanium-containing layer, the substantially monocrystalline germanium-containing layer and the second doped germanium-containing layer define a current flow path.

According to another aspect of the invention, methods for forming a photodetector device are provided. One method according to the invention comprises providing a substrate. A first doped germanium layer is formed on the substrate or on one or more intervening layers, the first doped germanium layer defining a buried layer. A substantially single crystal germanium layer is formed on the buried layer. A second doped germanium layer is formed on the single crystal germanium layer, the second doped germanium layer defining a contact layer. An electrically conductive contact extends from an upper surface of the photodetector device downward to the buried layer, the electrically conductive contact being electrically insulated from the single crystal germanium layer and the second doped germanium layer.

According to another aspect of the invention, methods for forming a photodetector device are provided. One method according to the invention comprises providing a substrate. A first doped germanium-containing layer is formed on the substrate or on one or more intervening layers, the first doped germanium-containing layer defining a buried layer. A substantially single crystal germanium-containing layer is formed on the buried layer. A second doped germanium-containing layer is formed on the single crystal germanium-containing layer, the second doped germanium-containing layer defining a contact layer. An electrically conductive contact extends from an upper surface of the photodetector device downward to the buried layer, the electrically conductive contact being electrically insulated from the single crystal germanium-containing layer and the second doped germanium-containing layer.

For purposes of summarizing the invention and the advantages achieved over the prior art, certain objects and advantages of the invention have been described above and as further described below. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments of the present invention will become readily apparent to those skilled in the art from the following detailed description of the preferred embodiments having reference to the attached figure, the invention not being limited to any particular preferred embodiment(s) disclosed.

### BRIEF DESCRIPTION OF THE DRAWING

The invention will be better understood from the Detailed Description of the Preferred Embodiments and from the appended drawing, which is meant to illustrate and not to limit the invention, and wherein:

FIG. 1 is a schematic, cross-sectional side view of a photodetector device, in accordance with a preferred embodiment of the invention.

### DETAILED DESCRIPTION OF THE PREFERRED EMBODIMENTS

In a preferred embodiment of the invention, a germanium-based photodetector is formed on a substrate. The device advantageously offers reduced lattice strain, enabling improved device performance, and geometry suitable for large-scale integration.

Definitions

For the purpose of the present invention, “buried layer” may designate a highly conductive film or contact at least one layer removed from the surface of the photodetector.

“Contact layer” may be used to designate a layer, film or thin film used to form at least one low resistivity electrical contact to the photodetector device.

“Seed layer” may designate a nucleation layer, film or thin film, which is a layer used to ensure a continuous film with little to no voids, holes, or defects.

“Intrinsic layer” may designate an intentionally substantially undoped (or lightly doped) layer. In some cases, an intrinsic layer may be unintentionally doped from one or more background gases.

Photodetector Device Structure

Reference will now be made to the figure. It will be appreciated that the figure is not necessarily drawn to scale. It will be further appreciated that the term “substrate,” as used herein, refers to its ordinary meaning, as well as to a bare wafer or to such a workpiece with layers already formed thereon.

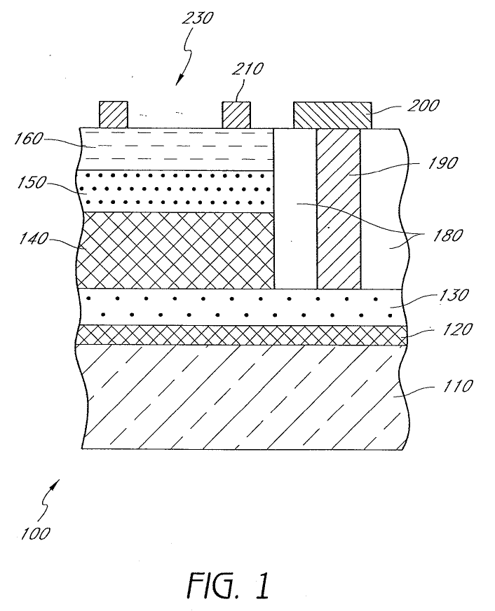

With reference to FIG. 1, in a preferred embodiment of the invention, a germanium-based photodetector structure 100 is shown. The structure 100 comprises, from bottom-to-top: a substrate 110, a seed or nucleation layer 120, a first doped (“doped”) germanium or germanium-containing layer 130, a substantially single crystalline (“single crystal”) or monocrystalline germanium germanium-containing layer 140, a second doped germanium or germanium-containing layer 150, a metal germanide layer 160, an electrically insulating layer (“insulating layer”) 180, an electrically conductive contact 190, a first electrode 200 and a second electrode 210. In an alternative embodiment, the layer 160 is defined by a metal silicide. The first doped germanium layer 130 defines a buried layer. The second doped germanium layer 150 defines a contact layer. The buried layer 130, the substantially single crystal germanium layer 140 and the contact layer 150 define an “active layer”. In a preferred embodiment, the buried layer 130, the single crystal germanium layer 140 and the contact layer 150 define a current flow path. In some embodiments, the buried layer 130 is formed on the substrate 100 without the intervening seed layer 120.

In preferred embodiments, layers 130, 140 and 150 have a substantially entirely germanium (Ge) content. As an example, layers 130, 140 and 150 may be germanium layers with little to no silicon (or other semiconductor) impurities. However, in some embodiments, at least one of layers 130, 140 and 150 may include silicon (i.e., at least one of layers 130, 140 and 150 is defined by SiₓGe₁₋ₓ, where ‘x’ is a number between 0 and 1). Preferably, the layers 130, 140 and 150 have the same germanium content, though in some embodiments the germanium content may vary.

With continued reference to FIG. 1, the substrate 110 is preferably a semiconductor wafer, more preferably a silicon wafer, most preferably a silicon wafer doped with a p-type dopant, such as, e.g., boron (B). As an alternative, the substrate 110 may include a silicon wafer doped n-type. As yet another alternative, the substrate 110 may be a wafer including a high resistivity material, such as, e.g., intrinsic silicon. The seed layer 120 is preferably a germanium layer. In one embodiment, the seed layer 120 is intrinsic. In another embodiment, the seed layer 120 is lightly doped p- or n-type. The single crystal germanium layer 140 is preferably intrinsic, though in some embodiments it may be lightly doped with a p- or n-type dopant. The first and second doped germanium layers 130,150 are doped with either n- or p-type dopants. N-type dopants include, without limitation, arsenic (As), phosphorous (P), and antimony (Sb). In a preferred embodiment, the first and second doped germanium layers 130,150 are alternately doped with n- or p-type dopants. For example, if the buried layer 130 is p-type, the contact layer 150 is n-type. Conversely, if the buried layer 130 is n-type, the contact layer 150 is p-type. In preferred embodiments, the substrate 110 and the buried layer 130 are alternately doped n- or p-type. That is, if the substrate 110 is n-type, the buried layer 130 is p-type, and vice versa.

With continued reference to FIG. 1, in a preferred embodiment, the seed layer 120 has a thickness of about one atomic monolayer (ML) to 100 nanometers (nm). In another embodiment, the seed layer 120 has a thickness between approximately two atomic MLs and 100 nm. In a preferred embodiment, the seed layer 120 is between approximately 3 Å and 60 nm thick.

In a preferred embodiment, the buried layer 130 has a thickness of about 50 nm to 200 nm, the single crystal germanium layer 140 has a thickness of about 1 micrometer to 5 micrometers and the contact layer 150 has a thickness of about 20 nm to 80 nm.

In a preferred embodiment, the electrically conductive contact 190 of the photodetector structure 100 comprises a trench or via preferably filled with a metal, more preferably one or more metals selected from the group consisting of copper (Cu), tungsten (W), titanium (Ti), tantalum (Ta), aluminum (Al) and nickel (Ni). As an alternative, the trench or via may be lined with a seed layer formed of, e.g., tungsten or tantalum nitride (TaN), and subsequently filled with a metal, preferably one or more metals selected from the group consisting of copper (Cu), tungsten (W), titanium (Ti), tantalum (Ta), aluminum (Al) and nickel (Ni). The trench or via may be formed in the insulating layer 180. The electrically conductive contact 190 is substantially electrically insulated from the single crystal germanium layer 140, the contact layer 150, and the metal germanide or silicide layer 160 by the insulating layer 180. The electrically conductive contact 190 has a resistivity substantially less than the resistivity of the insulating layer 180. The electrically conductive contact 190 is in electrical contact with the buried layer 130. In other embodiments, the electrically conductive contact 190 comprises a highly doped p- or n-type semiconductor. In such a case, if the buried layer 130 is doped p-type, the electrically conductive contact 190 is preferably also doped p-type, and if the buried layer 130 is doped n-type, the electrically conductive contact 190 is preferably also doped n-type.

With continued reference to FIG. 1, in a preferred embodiment of the invention, the first electrode 200 and the second electrode 210 are formed over the upper surface of the structure 100. The first and second electrodes 200,210 define front side contacts, wherein the electrodes 200,210 can be contacted through the front side of the photodetector structure 100. Front side contacts advantageously enable device incorporation into a wide variety of settings, including, but not limited to, electronics circuitry and semiconductor devices. The first electrode 200 is formed over the insulator 180 and electrically conductive contact 190. The second electrode 210 is formed over the metal germanide or silicide layer 160. The first electrode 200 is in electrical contact with the electrically conductive contact 190. The second electrode 210 is in electrical contact with the metal germanide or silicide layer 160.

In the illustrated embodiment, the second electrode 210 is ring-shaped. The interior of the second electrode 210 defines an exposed area 230 over the metal germanide or silicide layer 160. In other embodiments (now shown), the second electrode 210 is a substantially thin metal layer formed over the metal germanide or silicide layer 160. It will be appreciated that a variety of different shapes are possible for electrodes 200,210.

With continued reference to FIG. 1, when light is incident on the surface of the structure 100, generation of electron-hole pairs in the active layer produces a current in the structure 100 while an electrical potential is applied across the electrodes 200,210. The electrical potential may not be necessary if the intrinsic band-gap of the device structure is sufficient to generate a current. The current flows either from the first electrode 200 through the active layer to the second electrode 210, or from the second electrode 210 through the active layer to the first electrode 200.

In some embodiments, the structure 100 comprises an antireflective coating (ARC) layer (not shown). The ARC layer increases the quantum efficiency of the photodetector device. The ARC layer is formed of material including, but not limited to, silicon oxynitride and zinc sulfide. The ARC layer is preferably formed over the contact layer 150. For example, the ARC layer may be a substantially thin and conformal layer formed on the exposed area 230. As another example, the ARC layer may be a substantially thin layer formed over the second electrode 210. In other embodiments, the structure 100 comprises a reflective coating layer (not shown) formed below the substrate 110.

With continued reference to FIG. 1, the metal germanide or silicide layer 160 includes, without limitation, a metal or a plurality of metals and silicon, germanium or combinations thereof. For example, the layer 160 may be defined by nickel (Ni) germanium alloy (i.e., metal germanide). As another example, the layer 160 may be defined by a nickel-silicon alloy (i.e., metal silicide). As still another example, the layer 160 may be defined by a nickel-germanium-silicon alloy (i.e., metal germano silicide). As still another example, the layer 160 may be defined by a nickel-cobalt-titanium-silicon alloy.

In some embodiments, the metal germanide or silicide layer 160 is preferably doped with either a p- or n-type dopant, depending on the doping configuration of the contact layer 150. For example, if the contact layer 150 is doped p-type, the metal silicide layer 160 is preferably also doped p-type. In a preferred embodiment, the concentration of the p- or n-type dopant in the metal germanide or silicide layer 160 is substantially higher than the concentration of the p- or n-type dopant in the contact layer 150.

Methods of forming the structure 100 will now be described. It will be appreciated that forming comprises using methods selected from the group including, but not limited to, atomic layer deposition (ALD), chemical vapor deposition (CVD), physical vapor deposition (PVD), molecular beam epitaxy (MBE), low energy plasma enhanced chemical vapor deposition (LEPECVD), reduced pressure chemical vapor deposition (RPCVD) and ultrahigh vacuum chemical vapor deposition (UHVCVD).

Germanium Layers

Methods of forming germanium layers or films, including germanium films having improved physical characteristics, such as surface roughness and etch pit density, are known in the art and described in U.S. patent application Ser. No. 11/067,307 to Bauer et al, filed Feb. 25, 2005, the entire disclosure of which is incorporated herein by reference. Using certain methods described herein, germanium films can be deposited using conventional CVD processing equipment. In particular, the deposition preferably occurs in a sufficiently high pressure regime such that the use of UHVCVD is not necessarily required, and that better quality films are obtained. In some embodiments, the germanium films are deposited over a silicon-containing surface, such as a silicon substrate. In other embodiments, the germanium films are deposited over a patterned silicon wafer. In still other embodiments, the germanium films are deposited over other germanium films or layers.

Although this disclosure refers to germanium films, the techniques disclosed herein are also applicable to the fabrication of films comprising germanium (Ge) and other substances, including carbon (C), silicon (Si) and dopants, such as phosphorous (P), antimony (Sb), boron (B), gallium (Ga), arsenic (As) and the like.

The processes described herein are conducted in a suitable process chamber. Examples of suitable process chambers include, but are not limited to, batch furnaces and single wafer reactors. An exemplary chamber is a single wafer, horizontal gas flow reactor that is radiatively heated. Suitable reactors of this type are commercially available, and include the Epsilon® series of single wafer epitaxial reactors commercially available from ASM America, Inc. (Phoenix, Ariz.). Such a reactor is described in greater detail in U.S. Patent Application Publication 2002/0173130 (published 21 Nov. 2002), the entire disclosure of which is incorporated by reference herein.

In other embodiments, the processes described herein are performed in other reactors, such as in a reactor having a showerhead arrangement. Benefits in increased uniformity and deposition rates have been found particularly effective in the horizontal, single-pass, laminar gas flow arrangement of the Epsilon® chambers. A suitable manifold is used to supply the silicon precursor, surface active compound, and germanium precursor to the thermal CVD chamber in which the deposition is conducted. Gas flow rates are determined by routine experimentation, depending on the size of the deposition chamber. Such a reactor is capable of performing deposition operations at pressures between approximately 0.200 torr and 850 torr with chamber reinforcement, such as support ribs or curved quartz walls.

Exemplary processing steps in forming the germanium layers or films in the structure 100 will now be discussed. The processes disclosed herein are usable to form germanium films on a wide variety of substrates, such as silicon-containing substrates. In certain modified embodiments, germanium films are formed on substrates having a miscut, such as a miscut between approximately 4° and approximately 6°.

Seed Layer

In one embodiment of the invention, the seed layer 120 is formed over the substrate 110 prior to formation of the buried layer 130. In a preferred embodiment, the seed layer is formed of germanium. The seed layer 120 advantageously offers formation of layers 130, 140 and 150 with sufficiently low threading dislocation densities. The seed layer 120 is formed using deposition techniques known in the art, such as chemical vapor deposition (CVD) and ultrahigh vacuum chemical vapor deposition (UHVCVD). The seed layer 120 is deposited at a temperature sufficiently low to reduce or avoid islanding of the deposited material. Preferably, deposition of the seed layer 120 begins at less than approximately 450° C. In another embodiment, deposition of the seed layer 120 begins at less than approximately 350° C. In another embodiment, deposition of the seed layer 120 begins at approximately 330° C., more preferably at between approximately 330° C. and approximately 370° C. In another embodiment, deposition of the seed layer 120 begins at between approximately 330° C. and approximately 450° C.

In one embodiment, between approximately 200 sccm and approximately 1 slm of a 10% germanium precursor (for example, stored as 10% GeH₄ and 90% H₂) is supplied to the reaction chamber during deposition of the seed layer 120. In some embodiments, other germanium sources are used, such as digermane, trigermane and chlorinated germanium sources, with appropriate adjustment of flow rate, deposition temperature and pressure.

The pressure in the reaction chamber during deposition of the seed layer 120 is preferably between approximately 0.200 torr and approximately 850 torr. More preferably, the pressure in the reaction chamber during deposition of the seed layer 120 is between approximately 1 torr and approximately 760 torr. More preferably, the pressure in the reaction chamber during deposition of the seed layer 120 is between about 1 torr and about 760 torr, more preferably between about 50 torr and about 200 torr.

Where a selective deposition process on patterned wafers is to be performed, reduced reactor pressures advantageously reduce deposition rates on dielectric materials. In a preferred selective deposition embodiment, the pressure in the reaction chamber is between approximately 1 torr and approximately 100 torr. In a more preferred selective deposition embodiment, the pressure in the reaction chamber is between approximately 10 torr and approximately 20 torr. Selectivity is achievable on patterned wafers as deposition over silicon as compared to oxide even without any added etchant. In a modified embodiment, an etchant including chlorine, such as hydrochloric acid or Cl₂, is provided to the reaction chamber in a selective deposition process. In still other embodiments, hydrochloric acid is provided to the reaction chamber in a blanket deposition process.

Preferably, deposition of the seed layer 120 has a duration between about 1.5 minutes and about 6 minutes. More preferably, deposition of the seed layer 120 has a duration between about 2 minutes and about 4 minutes. More preferably, deposition of the seed layer 120 has a duration between about 3 minutes and about 4 minutes. In one embodiment, deposition of the seed layer 120 has a duration of less than about three minutes.

In some embodiments, following deposition of the seed layer 120, the substrate is annealed using a temperature ramp. During the temperature ramp, the temperature is increased at a rate of between approximately 100° C. min¹ and approximately 500° C. min⁻¹. More preferably, the temperature is increased at a rate of between approximately 200° C. min⁻¹ and approximately 400° C. min⁻¹. Most preferably, the temperature is increased at a rate of approximately 300° C. min⁻¹. Preferably, the temperature is increased until a temperature between approximately 500° C. and 938° C. is obtained. More preferably, the temperature is increased until a temperature between approximately 700° C. and 900° C. is obtained.

Buried Layer

An exemplary process for forming the first doped germanium layer (buried layer) 130 includes an optional cleaning or native oxide reducing operation, such as a hydrogen bake operation. The bake operation is followed by a subsequent cooling operation. In one embodiment, the buried layer 130 is deposited in a three-stage deposition process. In the first deposition stage, the seed layer 120 is deposited at low temperature, as described above. In the second deposition stage, which accompanies annealing the substrate after deposition of the seed layer 120, as described above, the germanium precursor is supplied while the temperature is rapidly increased, and while germanium deposition continues. In the third deposition stage, a layer of bulk germanium of desired thickness is formed over the seed layer 120. The third step optionally includes a post-deposition anneal operation. In a preferred embodiment, a doping precursor (“dopant”) is supplied with the germanium precursor to form the buried layer 130. In another embodiment, the dopant is supplied following formation of the layer of bulk germanium and prior to post-deposition annealing. In another embodiment, the dopant is supplied following post-deposition annealing.

Dopants include, but are not limited to, B₂H₆ or a gallium source (e.g., Ga(CH₃)₃) for p-type doping and AsH₃, PH₃, or an antimony source for n-type doping. In one embodiment, a dopant is supplied with the germanium precursor during film growth at a substrate temperature between about 700° C. and 900° C., preferably between about 800° C.-850° C., and a reactor pressure of approximately 20 torr. If a p-type buried layer is desired, 1 sccm of 1% B₂H₆ (for example, stored as 1% B₂H₆ and 99% H₂) may be supplied in an H₂ (20 slm) carrier gas. If an n-type buried layer is desired, approximately 1 sccm of a 1% PH₃ precursor or approximately 30 sccm of a 1% AsH₃ precursor may be supplied with H₂ (30 slm).

In another embodiment, the buried layer 130 is formed directly on the silicon substrate without the intervening seed layer 120 by rapidly increasing the substrate temperature to preferably between about 700° C. and 900° C., more preferably about 800° C., while supplying the germanium precursor into the reactor until a germanium layer of desired thickness is achieved. Supply of the precursor is then terminated and the substrate is subjected to an optional post-deposition annealing. In a preferred embodiment, a dopant is supplied with the germanium precursor to form the buried layer 130. In another embodiment, the dopant is supplied following formation of the layer of bulk germanium and before post-deposition annealing. In another embodiment, the dopant is supplied after the post-deposition annealing and may be followed by another annealing step.

Single Crystal Germanium Layer

In a preferred embodiment of the invention, a bulk or single crystal germanium layer, such as single crystal germanium layer 140 (FIG. 1), is formed following formation of the buried layer 130. In an exemplary embodiment, deposition of the single crystal germanium layer (“bulk deposition”) 140 occurs at a high and substantially constant temperature. In an exemplary embodiment, the pressure in the deposition chamber during bulk deposition remains substantially unchanged as compared to the pressure during deposition of the buried layer 130.

In a preferred embodiment, the single crystal germanium layer 140 is formed at a substrate temperature of approximately 700° C. to 900° C., preferably about 800° C.-850° C., using a germanium precursor (e.g., GeH₄, 200 sccm). A hydrogen carrier gas is typically supplied at a flow rate of approximately 30 slm and pressure of approximately 20 torr. The supply of the germanium precursor is maintained until a single crystal germanium layer, preferably an intrinsic single crystal germanium layer, of desired thickness is achieved.

To improve the smoothness of the single crystal germanium layer 140, an etchant is optionally provided to the reaction chamber during germanium deposition. In one embodiment, the etchant is hydrochloric acid. By planarizing the surface of the single crystal germanium layer 140, the “gliding” of threading dislocations is facilitated, thereby allowing a germanium film having reduced etch pit density to be produced.

In certain embodiments, a chlorine source is optionally provided to the reaction chamber during bulk deposition. In one embodiment, the chlorine source is distinct from the germanium source, such as HCl or Cl₂. For example, in one such embodiment, between about 25 to 200 sccm HCl is provided to the reaction chamber during bulk deposition. In another embodiment, between about 25 to 75 sccm HCl are provided to the reaction chamber during bulk deposition. In another embodiment, the chlorine source and the germanium source are provided by the same compound, such as by a chlorogermane. Examples of suitable chlorogermanes include, but are not limited to, GeCl₄. Other chlorine sources are used in other embodiments.

In such embodiments, the chlorine source reduces depletion effects during bulk deposition, thereby enhancing film uniformity and increasing the effect of precursor conversion, thereby resulting in a higher quality, faster growing single crystal germanium layer 140.

In some embodiments, the single crystal germanium layer 140 is lightly doped p-type, which may neutralize impurities in layer 140. In one embodiment, p-type doping is achieved by introducing 1 ccm B₂H₆ in an H₂ carrier gas (20 slm) with the germanium precursor during bulk deposition. In another embodiment, p-type doping is achieved by introducing the dopant after supply of the germanium precursor. In another embodiment, p-type doping is achieved by introducing the dopant after supply of the etchant and/or chlorine source. In a preferred embodiment, substantially light p-type doping is achieved by introducing a chlorine source gas (e.g., HCl), which advantageously ensures a high resistivity single crystal germanium layer.

Contact Layer

In a preferred embodiment, the germanium contact layer 150 is formed following formation of the single crystal germanium layer 140. In an exemplary embodiment, deposition of the contact layer (“contact deposition”) occurs at a high temperature and at a substantially constant temperature. In an exemplary embodiment, the pressure in the deposition chamber during contact deposition remains substantially unchanged as compared to the pressure during bulk deposition.

In a preferred embodiment, the contact layer 150 is formed at a substrate temperature of approximately 700° C. to 900° C., preferably about 800° C., using a germanium precursor (e.g., GeH₄, 200 sccm) and a dopant (e.g., B₂H₆ at 1 sccm for p-type doping and AsH₃ or PH₃ at 30 sccm for n-type doping). A hydrogen carrier gas is typically supplied at a flow rate of approximately 30 slm and a pressure of approximately 20 torr. The supply of the germanium precursor and the dopant is maintained until a contact layer of desired thickness is achieved. In another embodiment, the dopant is supplied after supply of the germanium precursor.

While certain carrier gas flow rates have been used with respect to the formation of the seed layer, the buried layer, the single crystal germanium layer and the contact layer, it will be appreciated that the carrier gas flow rates can vary from those specified for the formation of each layer.

Post-Deposition Annealing

In some embodiments, a post-deposition annealing is performed after deposition of the seed layer 120, buried layer 130, single crystal germanium layer 140 and/or contact layer 150. Annealing advantageously permits dislocations to glide out of a germanium layer or film. In one embodiment of the post-deposition annealing operation, the germanium film is held at approximately 930° C., and at atmospheric pressure for approximately five minutes. In another embodiment of the post-deposition annealing operation, a thermal cycling annealing process is performed, in which the germanium film is repeatedly heated and cooled for a predetermined time period. In an exemplary embodiment, the post-deposition anneal operation is a spike anneal. For example, in the aforementioned Epsilon® reactors, temperature is capable of being ramped as quickly as, for example, 200° C. min⁻¹ until a peak temperature of at most about 938° C. is reached. Even without any plateau annealing, in certain embodiments such a spike anneal is sufficient to drive out defects, particularly in films with high a germanium concentration.

Film Properties

Certain embodiments of the techniques disclosed herein create germanium films having advantageous properties, including etch pit density, surface roughness, and film thickness. While this invention is not bound by theory, it is believed that germanium films, especially germanium films that are relatively thin, and/or that have a relatively high germanium content, provide a medium in which the gliding propagation of dislocations in the film proceed at a high velocity. See, for example, R. Hull, “Metastable strained layer configurations in the SiGe/Si system,” EMIS Datareviews, Series No. 24: Properties of SiGe and SiGe:C, edited by Erich Kasper et al., INSPEC, 2000 (London, UK). This benefit is obtainable even without post-deposition annealing, although annealing is optionally performed.

Preferably, germanium layers or films having etch pit densities less than approximately 10⁶ cm⁻² are formed. More preferably, germanium films having etch pit densities less than approximately 10⁵ cm⁻² are formed. More preferably, germanium films having etch pit densities less than approximately 10⁴ cm⁻² are formed. Most preferably, germanium films having etch pit densities less than approximately 10³ cm⁻² are formed, as demonstrated in experiments. Lower etch pit densities, such as less than approximately 3×10² cm⁻², are attainable in highly doped germanium films. The etch pit densities provided in this disclosure are for “as deposited” germanium films, meaning that these etch pit densities are attainable without the benefit of post-deposition treatment (such as annealing or etching). The etch pit density parameters were obtained by creating a surface scan of the germanium film using 35 mL AcOH, 10 mL HNO₃, 5 mL HF and 8 mg I₂.

Preferably, individual germanium layers or films having “as deposited” surface roughness of less than approximately 20 angstroms (Å) root-mean-square (rms) are formed. More preferably, germanium films having surface roughness of less than approximately 10 Å rms are formed. Most preferably, germanium films having surface roughness of less than approximately 3 Å rms are formed.

Surface roughness of germanium films can be determined using atomic force microscopy (AFM). In one embodiment, film thickness non-uniformities are no more than about 1%, as determined by experiment.

In one particular embodiment, the buried layer 130, which is deposited at between approximately 700 Å min⁻¹ and 900 Å min⁻¹, has a resultant surface roughness of approximately 2.8 Å rms (2 monolayers) and a resultant etch pit density of approximately 10³ cm⁻². Particular process conditions used to obtain these results can include the general process sequences taught herein, including provision of a surface active compound during cool down. Additionally, the process conditions may include use of a three-step germanium deposition, in which a germanium seed layer 120 is deposited at low temperature (for example, at about 350° C. for a germane precursor), followed by temperature ramping to a higher temperature (for example, to between approximately 700° C. and 900° C.) while continuing to flow germane, and continued deposition at the higher temperature. Additionally, hydrogen gas may be supplied to the reactor at various flow rates (for example, at about 5 slm or greater) with pressures between approximately 1 torr and 760 torr.

In one embodiment, the processing steps to form the germanium layers described herein advantageously offer a reduced bandgap in the photodetector device 100. In a preferred embodiment, absorption in the L-band (1561-1620 nanometers) is increased relative to bulk germanium. In another embodiment, mechanical stress (strain) formed in the buried layer during cool-down to room temperature offers improvements in the responsivity of the photodetector device 100. This is due to differing thermal expansion coefficients of silicon and germanium. In another embodiment, incorporation of dopants into the germanium layers is achieved with non-uniformities in dopant concentration of less than about 2%.

Front Side Contacts

In a preferred embodiment, front side contacts, such as the first electrode 200, are formed by conventional lithography, which includes the steps of applying a mask, patterning the mask, etching the exposed portions of the mask and depositing a conductive material. The conductive material is preferably one or more metals, more preferably one or more metals selected from the group consisting of copper (Cu), tungsten (W), titanium (Ti), tantalum (Ta), aluminum (Al) and nickel (Ni). As an alternative, the trench or via may be lined with a seed layer formed of, e.g., tungsten or tantalum nitride (TaN), and subsequently filled with a metal, preferably one or more metals selected from the group consisting of copper (Cu), tungsten (W), titanium (Ti), tantalum (Ta), aluminum (Al) and nickel (Ni). The mask may include a hard mask, a soft mask or a plurality of hard and/or soft masks. The mask is applied, as desired, to prevent deposition on select portions of the structure 100. In other embodiments, the structures formed include protective layers, such as etch stop barriers and diffusion barriers.

In one embodiment, the first electrode 200 is formed after first forming the insulating layer 180 using deposition techniques known in the art, such as chemical vapor deposition (CVD). The insulating layer 180 is preferably formed of insulating material, such as a form of silicon oxide (e.g., SiO₂). A trench or via is subsequently formed in the insulating layer 180 by applying a mask, patterning the mask to expose a portion of the structure 100 on which the electrically conductive contact 190 is to be formed, and etching through the insulating layer 180 to the buried layer 130 using desirable etch chemistries, such as etch chemistries selective for the insulating layer 180 material, to form a trench and/or via. The trench and/or via is then filled with a metal, such as copper, using, e.g., electroplating or CVD, and subsequently planarized using chemical mechanical polishing (CMP) to form the electrically conductive contact 190. The steps of applying a mask, defining a portion of the mask to be etched, etching and depositing a metal, such as copper, may be repeated to form the first electrode 200. The second electrode 210 may be subsequently formed by depositing the metal germanide or silicide layer 160 using conventional photolithography to define a portion of the metal germanide or silicide layer 160 where metal (e.g., copper) is to be deposited, and depositing metal to form the second electrode 210.

In another embodiment, the contact 190 and electrode 200 are formed by first depositing a conductive layer over the buried layer 130 and in side contact with the layers 140, 150 and 160, applying a mask over the conductive layer, defining portions of the conductive layer to be etched, and etching through the conductive layer to the buried layer, the non-etched portion forming the electrically conductive contact 190. Next, the insulating layer 180 is formed by depositing insulating material in the area between the electrically conductive contact 190 and the single crystal germanium layer 140, the contact layer 150 and the metal germanide or silicide layer 160. The second electrode 210 may be subsequently formed by applying conventional photolithography to define a portion of the metal germanide or silicide layer 160 where metal (e.g., copper) is to be deposited, and depositing metal to form the second electrode 210.

In another embodiment, the first electrode 200 is formed by first forming the insulating layer 180 using deposition techniques known in the art, such as chemical vapor deposition (CVD), depositing a layer of a semiconductor (e.g., Si, Ge or GaAs) and doping the layer of the semiconductor with either a p- or n-type dopant to form the electrically conductive contact 190. The step of doping the layer of the semiconductor includes applying a mask and defining a region to be doped. A desirable p- or n-type dopant, such as, e.g., B₂H₆ or AsH₃, is subsequently supplied to form the electrically conductive contact 190. A post-deposition annealing step may follow the supply of the p- or n-type dopant. The first electrode 200 and the second electrode 210 are subsequently formed using conventional deposition and lithography techniques.

In a preferred embodiment, the metal germanide or silicide layer 160 is formed by conventional deposition techniques, such as, e.g., chemical vapor deposition (CVD), atomic layer deposition (ALD), or sputtering. In other embodiments, the metal germanide or silicide layer 160 is formed by selectively depositing material on the contact layer 150.

In one embodiment, the metal germanide or silicide layer 160 is formed by introducing a source chemical or a plurality of source chemicals until a layer of desired thickness is formed. In another embodiment, deposition of the metal germanide or silicide layer includes post-deposition annealing.

In one embodiment, if the layer 160 is to be defined by a metal germanide, a germanium precursor, such as, e.g., germane (GeH4), and an optional dopant (e.g., B₂H₆ for p-type doping and AsH₃ for n-type doping), are supplied at a substrate temperature of 500° C. or higher until a germanium layer of desired thickness is achieved. As an alternative, the dopant may be supplied following supply of the germanium precursor. After the germanium precursor is supplied, a metal (e.g., nickel), or a plurality of metals, may be deposited on the germanium layer to form the metal germanide layer. The metal may be deposited by any method known in the art, such as, e.g., ALD, CVD or PVD, at a substrate temperature (e.g., about 500° C. or higher) sufficient to form the metal germanide layer. An optional post-deposition anneal may follow the deposition of the metal. In another embodiment, metal germanide is formed following formation of the contact layer 150 by depositing metal on the contact layer 150 at a suitable substrate temperature (preferably 500° C. or higher), thereby converting a fraction of the contact layer 150 to a metal germanide layer 160.

In another embodiment, if the layer 160 is to be defined by a metal silicide, a doped p-or n-type silicon layer is deposited on the contact layer 150 from a silicon precursor, such as, e.g., silane (SiH₄), and a dopant (e.g., B₂H₆ for p-type doping and AsH₃ for n-type doping), at a substrate temperature of 500° C. or higher. The silicon layer advantageously prevents the formation of dislocations at the interface between the contact layer 150 and the metal silicide layer 160. Additional silicon may be deposited on the silicon layer by supplying a silicon precursor (and optional dopant) until a desired silicon layer thickness is achieved. Next, a metal (e.g., nickel), or a plurality of metals, may be deposited on the silicon layer to form the metal silicide layer. During metal deposition, the substrate temperature is preferably about 500° C. or higher. An optional post-deposition anneal may follow the deposition of the metal.

In at least some of the aforesaid embodiments, any element used in an embodiment can interchangeably be used in another embodiment unless such a replacement is not feasible.

It will be understood by those of skill in the art that numerous and various modifications can be made without departing from the spirit of the present invention. For example, the photodetector structure 100 may be formed on a silicon wafer. As another example, the photodetector structure 100 may be integrated into a BiCMOS device. Therefore, it should be clearly understood that the forms of the present invention are illustrative only and are not intended to limit the scope of the present invention. All modifications and changes are intended to fall within the scope of the invention, as defined by the appended claims.

I claim:

1. A photodetector device, comprising:
a substrate;
a first doped germanium-containing layer formed on the substrate or on one or more intervening layers, the first doped germanium-containing layer defining a buried layer;
a substantially monocrystalline germanium-containing layer formed on the buried layer;
a second doped germanium-containing layer formed on the substantially monocrystalline germanium-containing layer, the second doped germanium-containing layer defining a contact layer; and
an electrically conductive contact extending vertically from an upper surface of the photodetector device downward to the buried layer, the electrically conductive contact being substantially electrically insulated from the substantially monocrystalline germanium-containing layer and the second doped germanium-containing layer,
wherein the first doped germanium-containing layer, the substantially monocrystalline germanium-containing layer and the second doped germanium-containing layer define a current flow path.

2. The photodetector device of claim 1, further comprising a seed layer formed directly on the substrate, the first doped germanium-containing layer being formed on the seed layer.

3. The photodetector device of claim 1, wherein the monocrystalline germanium-containing layer is formed of intrinsic germanium.

4. The photodetector device of claim 1, wherein at least one of the first and second doped germanium-containing layers has a substantially germanium content.

5. The photodetector device of claim 1, further comprising an electrically insulating layer substantially surrounding the electrically conductive contact and electrically insulating the electrically conductive contact from the monocrystalline germanium-containing layer and the second doped germanium-containing layer.

6. The photodetector device of claim 5, wherein the electrically conductive contact has a resistivity substantially less than a resistivity of the electrically insulating layer.

7. The photodetector device of claim 1, wherein the electrically conductive contact comprises a trench or via filled with metal.

8. The photodetector device of claim 7, wherein the metal includes one or more metals selected from the group consisting of copper (Cu), tungsten (W), titanium (Ti) and tantalum (Ta).

9. The photodetector device of claim 1, wherein the substrate is a wafer including p-type silicon.

10. The photodetector device of claim 1, wherein the substrate is a wafer including n-type silicon.

11. The photodetector device of claim 1, wherein the substrate is a wafer including intrinsic silicon.

12. The photodetector device of claim 1, further comprising a reflective coating layer formed below the substrate.

13. The photodetector device of claim 1, further comprising a metal germanide layer formed on the second doped germanium-containing layer.

14. The photodetector device of claim 1, further comprising a metal silicide layer formed on the second doped germanium-containing layer.

15. The photodetector device of claim 1, further comprising a doped silicon layer formed on the second doped germanium-containing layer.

16. The photodetector device of claim 15, further comprising a metal silicide layer formed on the doped silicon layer.

17. The photodetector device of claim 1, further comprising an anti-reflective coating (ARC) layer formed over the second doped germanium-containing layer.

18. The photodetector device of claim 1, further comprising a first electrode positioned on the upper surface of the photodetector device and in contact with the electrically conductive contact, and a second electrode positioned over the second doped germanium-containing layer on the upper surface of the photodetector device, wherein the first electrode and second electrode are substantially electrically insulated from one another.

19. The photodetector device of claim 18, wherein the second electrode is substantially ring-shaped.

20. The photodetector device of claim 18, wherein the first electrode and second electrode define front side contacts.

21. The photodetector device of claim 1, wherein the first doped germanium-containing layer is p-type, the substantially monocrystalline germanium-containing layer is intrinsic and the second doped germanium-containing layer is n-type.

22. The photodetector device of claim 1, wherein the first doped germanium-containing layer is n-type, the substantially monocrystalline germanium-containing layer is intrinsic and the second doped germanium-containing layer is p-type.

23. The photodetector device of claim 1, wherein the first doped germanium-containing layer, the substantially monocrystalline germanium-containing layer and the second doped germanium-containing layer have a substantially entirely germanium content.

24. The photodetector device of claim 1, wherein at least one of the first doped germanium-containing layer, the substantially monocrystalline germanium-containing layer and the second doped germanium-containing layer includes silicon.

25. The photodetector device of claim 1, wherein the first doped germanium-containing layer, the substantially monocrystalline germanium-containing layer and the second doped germanium-containing layer have the same germanium content.

26. A method for forming a photodetector device, comprising:
providing a substrate;
forming a first doped germanium layer on the substrate or on one or more intervening layers, the first doped germanium layer defining a buried layer;
forming a substantially single crystal germanium layer on the buried layer;
forming a second doped germanium layer on the single crystal germanium layer, the second doped germanium layer defining a contact layer; and
forming an electrically conductive contact extending from an upper surface of the photodetector device downward to the buried layer, the electrically conductive contact being electrically insulated from the single crystal germanium layer and the second doped germanium layer.

27. The method of claim 26, wherein forming comprises using deposition methods selected from the group consisting of atomic layer deposition (ALD), chemical vapor deposition (CVD), physical vapor deposition (PVD), molecular beam epitaxy (MBE), low energy plasma enhanced chemical vapor deposition (LEPECVD), reduced pressure chemical vapor deposition (RPCVD) and ultrahigh vacuum chemical vapor deposition (UHVCVD).

28. The method of claim 26, further comprising forming a seed layer on the substrate, the first doped germanium layer being formed on the seed layer.

29. The method of claim 26, wherein the substantially single crystal germanium layer is formed of intrinsic germanium.

30. The method of claim 26, wherein the substantially single crystal germanium layer is lightly doped p-type.

31. The method of claim 26, wherein forming the substantially single crystal germanium layer comprises introducing a chlorine source selected from the group of hydrochloric acid (HCl), Cl₂ and chlorogermanes.

32. The method of claim 26, further comprising providing an electrically insulating material that laterally surrounds the electrically conductive contact and electrically insulates the electrically conductive contact from the single crystal germanium layer and the second doped germanium layer.

33. The method of claim 26, wherein the substrate is a wafer including p-type silicon.

34. The method of claim 26, wherein the substrate is a wafer including n-type silicon.

35. The method of claim 26, wherein the substrate is a wafer including intrinsic silicon.

36. The method of claim 26, further comprising forming a layer of a metal germanide on the second doped germanium layer.

37. The method of claim 26, further comprising forming a layer of a metal silicide on the second doped germanium layer.

38. The method of claim 26, further comprising forming a doped silicon layer on the second doped germanium layer.

39. The method of claim 38, further comprising forming a layer of a metal silicide on the doped silicon layer.

40. The method of claim 26, further comprising providing a first electrode on the upper surface of the photodetector device, wherein the first electrode is in contact with the electrically conductive contact, and providing a second electrode over the second doped germanium layer on the upper surface of the photodetector device, wherein the first electrode and second electrode are substantially electrically insulated from one another.

41. The method of claim 26, further comprising forming an anti-reflective coating (ARC) layer over the second doped germanium layer.

42. The method of claim 26, further comprising forming a reflective coating layer below the substrate.

43. The method of claim 26, wherein the first doped germanium layer is p-type, the substantially single crystal germanium layer is intrinsic and the second doped germanium layer is n-type.

44. The method of claim 26, wherein the first doped germanium layer is n-type, the substantially single crystal germanium layer is intrinsic and the second doped germanium layer is p-type.

45. The method of claim 26, wherein the electrically conductive contact is formed by filling a trench or via with metal.

46. The method of claim 45, wherein the metal includes one or more metals selected from the group consisting of copper (Cu), tungsten (W), titanium (Ti), tantalum (Ta) and nickel (Ni).

47. A method for forming a photodetector device, comprising:
providing a substrate;
forming a first doped germanium-containing layer on the substrate or on one or more intervening layers, the first doped germanium-containing layer defining a buried layer;
forming a substantially single crystal germanium-containing layer on the buried layer;
forming a second doped germanium-containing layer on the single crystal germanium-containing layer, the second doped germanium-containing layer defining a contact layer; and
forming an electrically conductive contact extending from an upper surface of the photodetector device downward to the buried layer, the electrically conductive contact being electrically insulated from the single crystal germanium-containing layer and the second doped germanium-containing layer.
